(19) United States
(12) Patent Application Publication
(10) Pub. No.: US 2015/0053475 A1
(43) Pub. Date: Feb. 26, 2015

(54) MULTI LAYERED PRINTED CIRCUIT BOARD

(71) Applicant: Samsung Electro-Mechanics Co., Ltd., Suwon-Si (KR)

(72) Inventor: Jung Keun Kim, Suwon-Si (KR)

(73) Assignee: Samsung Electro-Mechanics Co., Ltd., Suwon-Si (KR)

(21) Appl. No.: 14/463,489

(22) Filed: Aug. 19, 2014

(30) Foreign Application Priority Data
Aug. 20, 2013 (KR) 10-2013-0098593

(51) Int. Cl. H05K 1/11; H05K 1/02

(52) U.S. Cl. CPC H05K 1/115; H05K 1/0298; H05K 2201/09836; H05K 2201/0959
USPC 174/266

(57) ABSTRACT

There is provided a multi layered printed circuit board. The multi layered printed circuit board according to an exemplary embodiment of the present disclosure includes: a plurality of circuit layers; insulating layers each formed between the plurality of circuit layers; and a via penetrating through the insulating layers and the circuit layers and electrically connecting the plurality of circuit layers to each other, wherein the via includes a first via and a second via, and the second via is a large diameter via having a diameter larger than that of the first via.

### CROSS-REFERENCE TO RELATED APPLICATION

This application claims the foreign priority benefit of Korean Patent Application No. 10-2013-0098593, filed on Aug. 20, 2013, entitled “Multi Layered Printed Circuit Board” which is hereby incorporated by reference in its entirety into this application.

### BACKGROUND

Embodiments of the present disclosure relate to a multi layered printed circuit board.

A printed circuit board (PCB), which is formed by printing circuit line patterns made of a conductive material such as copper on an electrical insulating substrate, refers to a board immediately before electronic components are mounted thereon.

That is, the PCB refers to a circuit board in which a mounting position of each component is determined and a circuit pattern connecting the components is printed and fixed on a flat panel surface, in order to densely mount various kinds of electronic elements on a flat panel.

The above-mentioned PCB generally includes a single layer PCB and a build-up board, that is, a multi layered printed circuit board in which the PCBs are formed in a multilayer.

Digital devices such as a smart phone, a tablet PC, and the like have been recently required to implement high performance, miniaturization, a fast transmission speed, and an increase in transmit data capacity.

Accordingly, high operating frequency, wideband and multi-band characteristics, and the like are required.

For example, since a main board (CPU), an application processor (AP), a power amplifier, a radio frequency (RF) component, and the like which are used in the smart phone use high consumption current, a structure of the printed circuit board capable of improving a current flow has been required.

### RELATED ART DOCUMENT

### Patent Document

(Patent Document 1) Japanese Patent Laid-Open Publication No. 2006-120858

### SUMMARY

An aspect of the present disclosure may provide a differentiated large diameter via (OTH VIA) structure capable of improving a current flow as compared to a via on an existing bare PCB.

An aspect of the present disclosure may also provide a structure capable of effectively implementing a design by using both an inner via and a stack via as a power line wiring having a large current amount.

An aspect of the present disclosure may also provide a structure capable of increasing heat radiating effect by increasing a maximum current amount which is transferable through a via.

According to an aspect of the present disclosure, a multi layered printed circuit board may include: a plurality of circuit layers; insulating layers each formed between the plurality of circuit layers; and a via penetrating through the insulating layers and the circuit layers and electrically connecting the plurality of circuit layers to each other, wherein the via includes a first via and a second via, and the second via is a large diameter via having a diameter larger than that of the first via.

The second via may include an inner via and a stack via.

The second via may have a plane shape of an oval.

The second via may configure a power system wiring.

The second via may have a plating amount larger than that of the first via by 1.3 to 1.4 times.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of a multi layered printed circuit board in which first and second vias are formed;

FIG. 2 is a cross-sectional view in which the first via is changed to a second via structure; and

FIG. 3 is a cross-sectional view in which the first via is changed to the second via structure.

### DETAILED DESCRIPTION

The aspects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### Multi Layered Printed Circuit Board

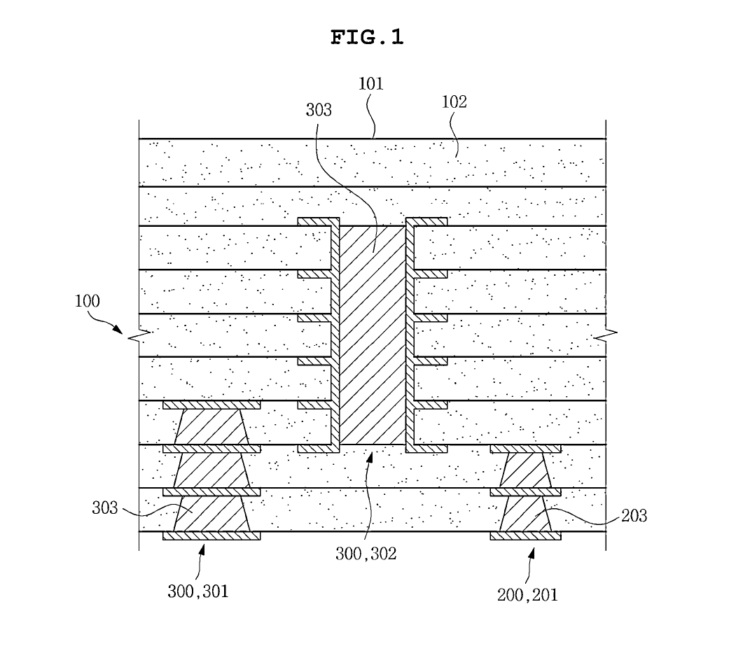

Referring to FIG. 1, a multi layered printed circuit board 100 according to an exemplary embodiment of the present disclosure includes a plurality of circuit layers 101, insulating layers 102 each formed between the plurality of circuit layers 101, and a via penetrating through the insulating layers 102 and the circuit layers 101 and electrically connecting the plurality of circuit layers 101 to each other.

Here, the via includes a first via 200 and a second via 300, and the second via 300 is a large diameter via larger than a diameter of the first via 200.

In this case, the second via 300 may include an inner via and a stack via.

In addition, the second via 300 may has a plane shape of an oval.

Here, the second via 300 may configure a power system wiring.

The second via 300 has the most important advantage that it may be used in a power line having a large amount of current. The first via 200 is mainly used in a signal line wiring and the second via 300 is used in the power system wiring as well as the signal system wiring.

Further, the present disclosure may effectively implement a design using both a second inner via 302 and a second stack via 301 as the power system wiring having the large current amount.

In addition, an amount of plating 303 of the second via may be 1.3 to 1.4 times of an amount of plating 203 of the first via.

Since a diameter size of the second via 300 is larger than that of the first via 200, a hole plating amount in the second via 300 is larger than that in the first via 200 by about 1.3 to 1.4 times. However, the above-mentioned numerical values are not limited thereto, but the numerical values may also be changed as the diameter size of the via is changed.

When comparing the first via 200 and the second via 300 with each other in the same region, the second via 300 has a copper (Cu) content higher than the first via 200, thereby making it possible to improve the current flow.

Since the second via 300 has a copper (Cu) volume amount higher than the first via 200, it has an improved current flow.

Further, the second via 300 may increase a maximum current amount which is transferable therethrough, thereby increasing heat radiating effect.

Here, the improved current flow means that a resistance value is small. When comparing with the first via 200, a current resistance value of the second via 300 may be smaller.

In addition, quantity of heat generated when the resistance value is decreased in a predetermined voltage and current, may also be decreased. In a case of the second via 300 disclosed in the present disclosure, the generated quantity of heat may be smaller than that of the first via 200.

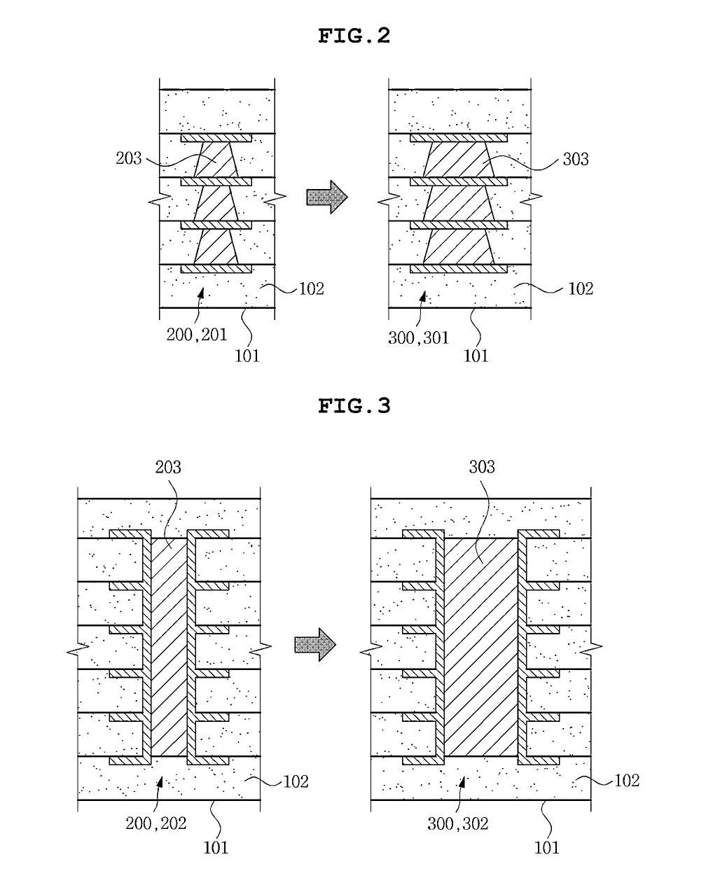

Referring to FIG. 2, FIG. 2 shows a stack via according to an exemplary embodiment of the present disclosure.

For example, assuming that the stack via has been formed from one layer to a four-layer on the multi layered printed circuit board, in the case in which a land size of a first stack via 201 is 250 and a hole size thereof is 100, the Cu content is 3,925,000 μm³ and in the case in which a land size of a second stack via 301 is 500 and a hole size thereof is 350, the Cu content is 4,462,500 μm³, such that it may be appreciated that the Cu content is increased by about 114%.

Here, it may be appreciated that a current flow of the second stack via 301 is improved by 114%.

In other words, the improved current flow may refer to a decreased resistance value.

Here, it may be appreciated from

$$Resistance ( R ) = \begin{matrix}Specific \\ Resistance\end{matrix} ( ρ ) \times \frac{Length ( l )}{Unit Area ( s )}$$

capable of understanding an action interrupting the current flow that the resistance value of the second stack via 301 is decreased by about 87.8%.

In addition, it may also be appreciated from a relationship Quantity of Heat (Q)=Voltage (F)×Current (I)×Time (T)=Square of Current (I²)×Resistance (R)×Time (T) between a resistance and quantity of heat that the quantity of heat is also decreased.

Therefore, it may be appreciated that quantity of heat of the second stack via 301 is decreased by about 87.8%.

Although effective aspects achieved by a structure of the second stack via 301 of the present disclosure have been described with the above-mentioned Equations and numerical values, the numerical values are according to an exemplary embodiment of the present disclosure and a current flow value, a resistance value, and the quantity of heat through the Cu content may be changed depending on a design condition of the second stack via 301.

Referring to FIG. 3, FIG. 3 shows an inner stack via according to another exemplary embodiment of the present disclosure.

For example, assuming that the inner via has been formed from a four-layer to a nine-layer on the multi layered printed circuit board, in the case in which a land size of a first inner via 202 is 450 and a hole size thereof is 200, the Cu content is 6,673,128 μm³ and in the case in which a land size of a second inner via 302 is 900 and a hole size thereof is 650, the Cu content is 7,890,564 μm³, such that it may be appreciated that the Cu content is increased by about 118%.

Here, it may be appreciated that a current flow of the second inner via 302 is improved by 118%.

In other words, the improved current flow may refer to a decreased resistance value.

Here, it may be appreciated from

$$Resistance ( R ) = \begin{matrix}Specific \\ Resistance\end{matrix} ( ρ ) \times \frac{Length ( l )}{Unit Area ( s )}$$

capable of understanding an action interrupting the current flow that the resistance value of the second inner via 302 is decreased by about 84.7%.

In addition, it may also be appreciated from a relationship Quantity of Heat (Q)=Voltage (V)×Current (I)×Time (T)=Square of Current (I²)×Resistance (R)×Time (T) between a resistance and quantity of heat that the quantity of heat is also decreased.

Therefore, it may be appreciated that quantity of heat of the second inner via 302 is decreased by about 84.7%.

Although effective aspects achieved by a structure of the second inner via 302 of the present disclosure have been described with the above-mentioned Equations and numerical values, the numerical values are according to another exemplary embodiment of the present disclosure and a current flow value, a resistance value, and the quantity of heat through the Cu content may be changed depending on a design condition of the second inner via 302.

As set forth above, according to the exemplary embodiments of the present disclosure, the multi layered printed circuit board may improve the current flow as compared to the existing via.

Further, the design may be effectively implemented by using both the inner via and the stack via as the power line wiring having the large current amount.

Further, the heat radiating effect may be increased by increasing the maximum current amount which is transferable through the via.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A multi layered printed circuit board comprising:
a plurality of circuit layers;
insulating layers each formed between the plurality of circuit layers; and
a via penetrating through the insulating layers and the circuit layers and electrically connecting the plurality of circuit layers to each other,
wherein the via includes a first via and a second via, and the second via is a large diameter via having a diameter larger than that of the first via.

2. The multi layered printed circuit board of claim 1, wherein the second via includes an inner via and a stack via.

3. The multi layered printed circuit board of claim 1, wherein the second via has a plane shape of an oval.

4. The multi layered printed circuit board of claim 1, wherein the second via configures a power system wiring.

5. The multi layered printed circuit board of claim 1, wherein the second via has a plating amount larger than that of the first via by 1.3 to 1.4 times.
